(19) United States
(12) Patent Application Publication
(10) Pub. No.: US 2017/0053860 A1
(43) Pub. Date: Feb. 23, 2017

(54) HIGH-FREQUENCY, HIGH-OUTPUT DEVICE UNIT

(71) Applicant: Mitsubishi Electric Corporation, Tokyo (JP)

(72) Inventors: Takashi TSURUMAKI, Tokyo (JP); Katsumi MIYAWAKI, Tokyo (JP)

(73) Assignee: Mitsubishi Electric Corporation, Tokyo (JP)

(21) Appl. No.: 15/142,990

(22) Filed: Apr. 29, 2016

(30) Foreign Application Priority Data
Aug. 20, 2015 (JP) 2015-162536

(51) Int. Cl. H01L 23/498; H01L 23/66; H01L 23/15; H01L 23/492

(52) U.S. Cl. CPC H01L 23/49838; H01L 23/492; H01L 23/66; H01L 23/49805; H01L 23/15; H01L 23/49811

(57) ABSTRACT

A high-frequency, high-output device unit includes a lead intended to be soldered to a circuit board and the lead includes concave portions only in a planar portion intended to be joined to the circuit board.

### BACKGROUND OF THE INVENTION

Field

The present invention relates to a high-frequency, high-output device unit, and more particularly, to a high-frequency, high-output device unit suitable for use in a cellular phone base station.

Background

Inside semiconductor packages used for high-frequency, high-output device units, a semiconductor chip and circuit parts are mounted on an upper surface of a base plate, and these parts and a lead are connected using a gold wire. The lead plays a role as an electrode for connecting the high-frequency, high-output device unit and a circuit board on which the unit is mounted (hereinafter also referred to as “target circuit board”).

Wide leads are often adopted for high-output capable units with a frequency band used for cellular phone base stations among high-frequency, high-output device units in consideration of an impedance and a high current (e.g., see JP2-72004 U).

When a high-frequency, high-output device unit provided with a wide lead is mounted on a target circuit board using solder, large stress may be applied to the solder between the target circuit board and the lead. Such stress is generated due to a difference in coefficients of linear expansion between parts constituting the high-frequency, high-output device unit and the target circuit board.

Once cracking occurs in the solder due to a temperature difference depending on an operating environment, the cracking may readily propagate in a linear form along a bonded interface between the lead and solder, and the solder may be fractured in early stages.

### SUMMARY OF THE INVENTION

The present invention has been implemented in view of the above-described problems and it is an object of the present invention to enhance durability against breakage of solder when soldering a wide lead to a target circuit board.

The features and advantages of the present invention may be summarized as follows.

According to the present invention, a high-frequency, high-output device unit includes a lead intended to be soldered to a circuit board, wherein the lead comprises a concave portion only in a planar portion intended to be joined to the circuit board.

Other and further objects, features and advantages of the invention will appear more fully from the following description.

### BRIEF DESCRIPTION OF THE DRAWINGS

FIG. 1 is a perspective view illustrating a high-frequency, high-output device unit according to a first embodiment of the present invention.

FIG. 2 is three orthographic views of the high-frequency, high-output device unit 10.

FIG. 3 is three orthographic views illustrating the high-frequency, high-output device unit according to the first embodiment of the present invention mounted on a circuit board.

FIG. 4 is a cross-sectional view, which is an enlarged view of a structure of a frame portion shown by a single-dot dashed line in FIG. 3.

FIG. 5 is a plan view of the high-frequency, high-output device unit according to the first embodiment of the present invention and a cross-sectional view obtained by cutting the present unit along a straight line V-V.

FIG. 6 is a cross-sectional view of the portion of the lead when the high-frequency, high-output device unit according to the first embodiment of the present invention is mounted on the circuit board.

FIG. 7 is a plan view of the high-frequency, high-output device unit according to a second embodiment of the present invention and a cross-sectional view obtained by cutting the present unit along a straight line VII-VII.

FIG. 8 is a plan view of the high-frequency, high-output device unit according to a third embodiment of the present invention.

FIG. 9 is a plan view of the high-frequency, high-output device unit according to a fourth embodiment of the present invention.

FIG. 10 is a plan view of the high-frequency, high-output device unit according to a fifth embodiment of the present invention.

FIG. 11 is a plan view of the high-frequency, high-output device unit according to a sixth embodiment of the present invention.

FIG. 12 is a plan view of the high-frequency, high-output device unit according to a seventh embodiment of the present invention.

### DESCRIPTION OF EMBODIMENTS

A high-frequency, high-output device unit according to an embodiment of the present invention will be described with reference to the attached drawings. Identical or corresponding components may be assigned identical reference numerals and duplicate description may be omitted.

### First Embodiment

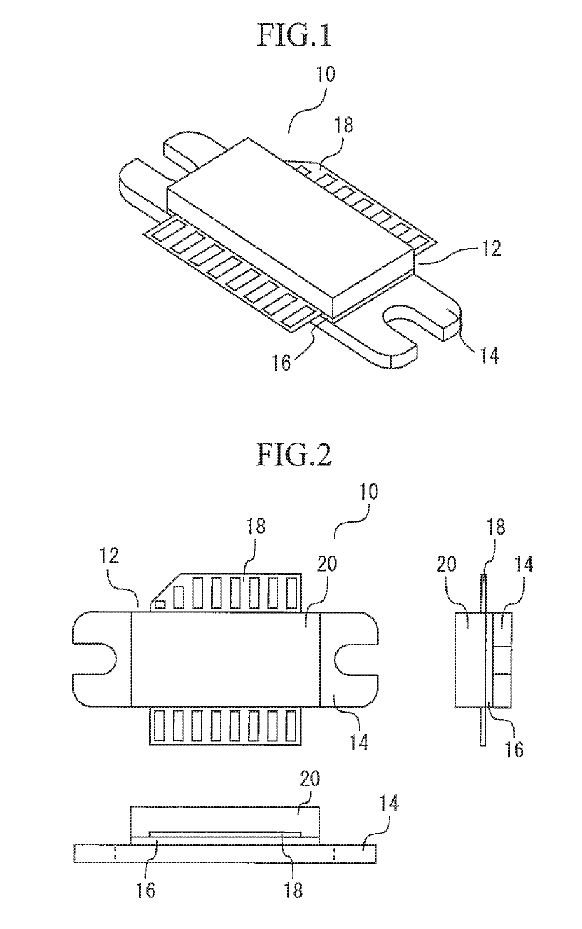

FIG. 1 is a perspective view illustrating a high-frequency, high-output device unit 10 according to a first embodiment of the present invention. FIG. 2 is three orthographic views of the high-frequency, high-output device unit 10 shown in FIG. 1. The high-frequency, high-output device unit 10 of the present embodiment has a frequency band of 800 MHz to 3.5 GHz and output power of 100 W to 300 W, and is intended for use in a cellular phone base station.

As shown in FIG. 2, a semiconductor package 12 used for the high-frequency, high-output device unit 10 of the present invention has a base plate 14. A ceramic frame 16 is mounted on the base plate 14. A lead 18 for connection with a target circuit board is mounted on the ceramic frame 16. The lead 18, the base plate 14 and the ceramic frame 16 are fixed using an Ag brazing material. Furthermore, a ceramic cap 20 is fixed to an upper surface of the ceramic frame 16 using an epoxy resin adhesive.

The lead 18 extends from both of mutually opposite sides of the semiconductor package 12. The lead 18 has a shape in which one side is longer than the other and the side in a longitudinal direction of the lead 18 is in contact with the semiconductor package 12. Inside the semiconductor package 12, a semiconductor chip and circuit parts, which are not shown, are mounted on an upper surface of the base plate 14. The semiconductor chip, the circuit parts and the lead 18 are connected together via a gold wire.

FIG. 3 is three orthographic views illustrating the high-frequency, high-output device unit 10 according to the first embodiment of the present invention mounted on a circuit board 21.

In the present embodiment, the circuit board 21 is constructed of a heat sink member 22 and organic circuit boards 24. The organic circuit board 24 includes a wiring pattern 26 on its upper surface intended to be soldered to the lead 18. The organic circuit boards 24 are disposed on both sides of an upper surface of the heat sink member 22. The high-frequency, high-output device unit 10 is disposed on the upper surface of the heat sink member 22 between the organic circuit boards 24. The high-frequency, high-output device unit 10 is fixed by fixing the base plate 14 to the upper surface of the heat sink member using screws 28. Note that the organic circuit board 24 can be substituted by a ceramic circuit board. The high-frequency, high-output device unit 10 may be fixed through soldering instead of the screws 28.

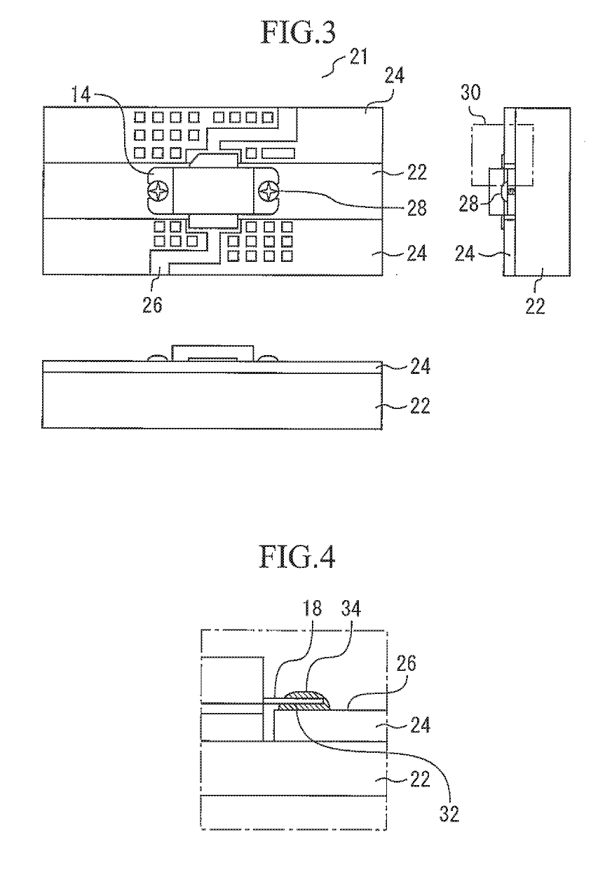

FIG. 4 is a cross-sectional view of a portion of the lead 18, which is an enlarged view of a structure of a frame portion 30 shown by a single-dot dashed line in FIG. 3. The lead 18 is soldered to the wiring pattern 26. Hereinafter, a surface of the lead 18 opposite to the wiring pattern 26 and intended to be joined to the wiring pattern 26 is assumed to be a planar portion 32.

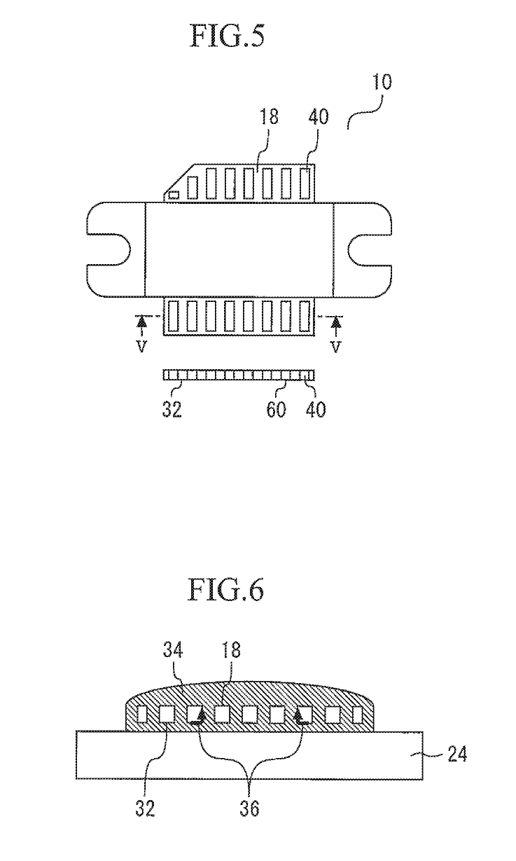

FIG. 5 is a plan view of the high-frequency, high-output device unit 10 according to the first embodiment of the present invention and a cross-sectional view obtained by cutting the present unit along a straight line V-V. A plurality of openings 40 are provided in the lead 18 and concave portions 60 are thereby formed on the planar portion 32. The opening 40 has a rectangular shape which is oblong in a traverse direction of the lead 18. The size and the number of openings are not limited to the example shown in FIG. 5.

When the lead 18 is joined to the wiring pattern 26, soldering is performed at a high temperature. Therefore, the solder 34 coagulates while having residual stress produced by a difference in coefficients of linear expansion between the parts making up the high-frequency, high-output device unit 10 and the circuit board 21. Furthermore, stress is repetitively applied to the solder 34 due to a temperature variation depending on an operating environment. Such stress may cause cracking in the solder 34 along the planar portion 32 with the passage of time and may cause breakage of the joining.

Stress caused by a difference in coefficients of linear expansion is applied to the contact portion of the solder 34 with the planar portion 32. When there is no opening 40, the entire planar portion 32 comes into contact with the solder 34. Therefore, stress produced from the entire planar portion 32 is added to the solder 34. In contrast, with the presence of the openings 40, contact between the planar portion 32 and the solder 34 is discontinued in the openings. Therefore, stress applied to the solder 34 is reduced in the openings. Therefore, provision of the openings 40 can reduce stress applied to the contact portion of the solder 34 with the planar portion 32 and suppress generation of cracks.

FIG. 6 is a cross-sectional view of the portion of the lead 18 when the high-frequency, high-output device unit 10 according to the first embodiment of the present invention is mounted on the circuit board 21. Cracks generally occur along the planar portion 32 and propagate linearly. According to the present embodiment, when a crack generated along the planar portion 32 collides with the opening 40 as shown by an arrow 36, the crack is bent in the thickness direction of the solder 34 and enters the opening 40. Therefore, according to the present embodiment, after a crack is generated, it is possible to prevent the crack from propagating linearly. Thus, it is possible to enhance durability against breakage of the solder 34 and extend the product life of a module on which the unit is mounted.

### Second Embodiment

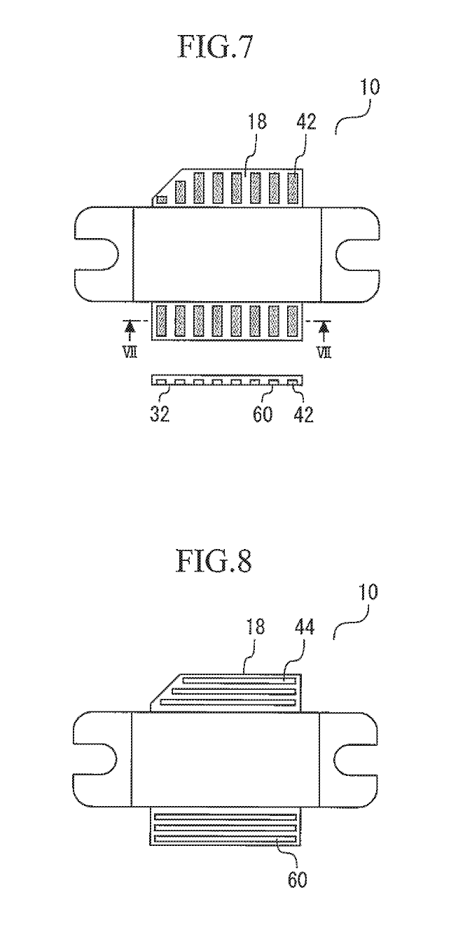

FIG. 7 is a plan view of the high-frequency, high-output device unit 10 according to a second embodiment of the present invention and a cross-sectional view obtained by cutting the present unit along a straight line VII-VII. The present embodiment is similar to the first embodiment except in that the openings 40 are replaced by grooves 42. In the present embodiment, concave portions 60 are formed in the planar portion 32 by providing the plurality of grooves 42 in the planar portion 32. The plan view shown in FIG. 7 expresses the high-frequency, high-output device unit 10 in a top view. Therefore, the grooves 42 originally do not appear in the plan view, but the positions of the grooves 42 are shown here by hatching for convenience. The depth of the grooves 42 is on the order of half the thickness of the lead 18. The invention is not particular about the width, depth, cross-sectional shape and quantity of grooves.

According to the present embodiment, as with the first embodiment, after a crack is generated, the grooves 42 can prevent the crack from linearly propagating. Therefore, it is possible to enhance durability against breakage of the solder 34 and extend the product life of a module on which the unit is mounted.

### Third Embodiment

FIG. 8 is a plan view of the high-frequency, high-output device unit 10 according to a third embodiment of the present invention. The present embodiment is similar to the first embodiment except in that openings 44 are oblong in the longitudinal direction of the lead 18. In the present embodiment, concave portions 60 are formed in the planar portion 32 by providing the plurality of openings 44 in the lead 18.

As in the case of the first embodiment, the presence of the openings 44 causes contact between the planar portion 32 and the solder 34 to be discontinued and reduces stress applied to the contact portion of the solder 34 with the planar portion 32. Therefore, it is possible to prevent generation of cracks.

According to the present embodiment, as with the first embodiment, after a crack is generated, the openings 44 can prevent the crack from linearly propagating. Therefore, it is possible to enhance durability against breakage of the solder 34 and extend the product life of a module on which the unit is mounted.

Tensile stress may occur between the circuit board 21 and the high-frequency, high-output device unit 10. When the lead 18 is soldered to the wiring pattern 26, both sides of the high-frequency, high-output device unit 10 are fixed. For this reason, tensile stress functions in the traverse direction of the lead 18. When there is no opening 44 in the lead 18, tensile stress generated from the entire planar portion 32 acts on the solder 34. With the provision of the openings 44, the lead 18 is discontinued in the direction of tensile stress. Therefore, the lead 18 is more likely to deform in the direction of tensile stress. For this reason, of the stress applied to the contact portion of the solder 34 with the planar portion 32, stress caused by the tensile stress is reduced. Therefore, it is possible to prevent generation of cracks.

### Fourth Embodiment

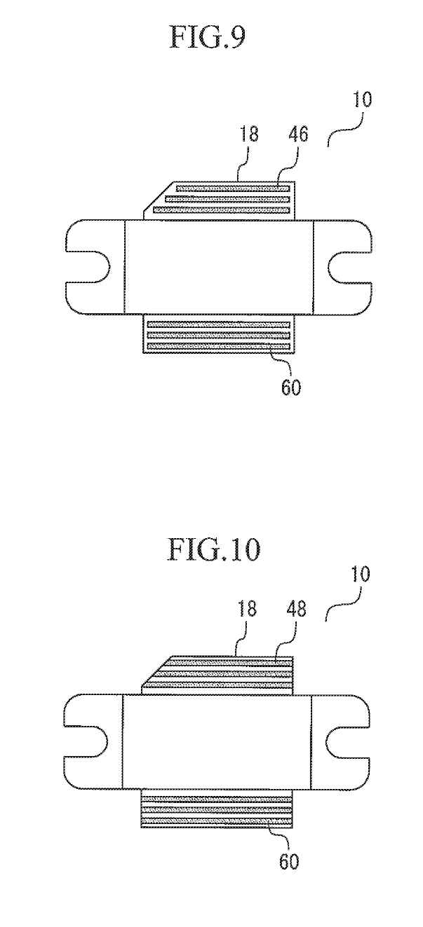

FIG. 9 is a plan view of the high-frequency, high-output device unit 10 according to a fourth embodiment of the present invention. The present embodiment is similar to the third embodiment except in that the openings 44 are replaced by grooves 46.

According to the present embodiment, as with the first embodiment, after a crack is generated, the presence of the grooves 46 can prevent the crack from propagating linearly. Thus, it is possible to enhance durability against breakage of the solder 34 and extend the product life of a module on which the unit is mounted.

Provision of the grooves 46 causes a thin portion to be formed in the lead 18 in the direction of tensile stress. Thus, as with the third embodiment, the lead 18 is more likely to deform in the direction of tensile stress. Therefore, it is possible to prevent generation of cracks.

### Fifth Embodiment

FIG. 10 is a plan view of the high-frequency, high-output device unit 10 according to a fifth embodiment of the present invention. The present embodiment is similar to the forth embodiment except in that grooves 48 are consecutively provided from one end of the lead 18 to the opposing end of the lead 18.

According to the present embodiment, as with the first embodiment, after a crack is generated, the grooves 48 can prevent the crack from propagating linearly. Thus, it is possible to enhance durability against breakage of the solder 34 and extend the product life of a module on which the unit is mounted.

Furthermore, in the case of the fourth embodiment, no groove is formed at the ends of the lead 18. In these portions, the lead 18 has high rigidity and strong stress is more likely to act. In contrast, in the present embodiment, provision of the grooves 48 from the end of the lead 18 can further reduce stress compared to the fourth embodiment.

### Sixth Embodiment

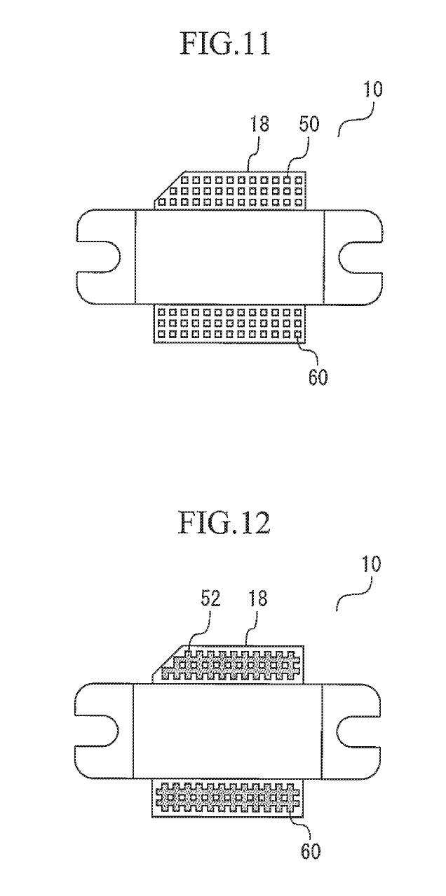

FIG. 11 is a plan view of the high-frequency, high-output device unit 10 according to a sixth embodiment of the present invention. In the present embodiment, the lead 18 is provided with a plurality of square openings 50 and the concave portions 60 are thereby formed in the planar portion 32. The openings 50 are disposed at grid points. The shape of the openings 50 may be other than square and the present invention is not particular about the number or arrangement of openings.

As with the first embodiment, the openings 50 cause the contact between the planar portion 32 and the solder 34 to be discontinued and thereby reduces stress applied to the contact portion of the solder 34 with the planar portion 32. Therefore, it is possible to prevent generation of cracks.

According to the present embodiment, as with the first embodiment, after a crack is generated, the openings 50 can prevent the crack from linearly propagating. Therefore, it is possible to enhance durability against breakage of the solder 34 and extend the product life of a module on which the unit is mounted.

### Seventh Embodiment

FIG. 12 is a plan view of the high-frequency, high-output device unit 10 according to a seventh embodiment of the present invention. In the present embodiment, grooves 52 are formed in the planar portion 32, and the concave portions 60 are thereby formed in the planar portion 32. The grooves 52 are formed into a grid shape with rectangular grooves being disposed so as to cross each other in the traverse direction and the longitudinal direction of the lead 18. The depth of the grooves 52 is on the order of half the thickness of the lead 18. The present invention is not particular about the width, depth, cross-sectional shape and number of grooves.

According to the present embodiment, as with the first embodiment, after a crack is generated, the grooves 52 can prevent the crack from linearly propagating. Therefore, it is possible to enhance durability against breakage of the solder 34 and extend the product life of a module on which the unit is mounted.

Furthermore, as with the third embodiment, when tensile stress occurs between the circuit board 21 and the high-frequency, high-output device unit 10, the grooves 52 reduce tensile stress. Therefore, it is possible to prevent generation of cracks.

Note that the lead 18 is provided on both sides of the high-frequency, high-output device unit 10 in the first to seventh embodiments, but the lead 18 may be provided on only a single side of the high-frequency, high-output device unit 10.

Obviously many modifications and variations of the present invention are possible in the light of the above teachings. It is therefore to be understood that within the scope of the appended claims the invention may be practiced otherwise than as specifically described.

In the present invention, a concave portion is provided on a planar portion of the lead. Cracks generally occur at a bonded interface between the lead and solder, and propagate along the interface in a linear form. According to the present invention, the concave portion causes a direction in which a crack propagates to bend to a thickness direction of the solder, and can thereby prevent the crack from propagating. Therefore, it is possible to enhance durability against breakage of the solder.

1. A high-frequency, high-output device unit comprising a lead intended to be soldered to a circuit board,
wherein the lead comprises a concave portion only in a planar portion intended to be joined to the circuit board.

2. The high-frequency, high-output device unit according to claim 1, wherein the concave portion provided in the lead is an opening.

3. The high-frequency, high-output device unit according to claim 1, wherein the concave portion provided in the lead is a groove.

4. The high-frequency, high-output device unit according to claim 2,
wherein the lead has such a shape that one side is longer than the other,
the side of the lead in a longitudinal direction is in contact with a semiconductor package, and
the concave portion provided in the lead is oblong in a traverse direction of the lead.

5. The high-frequency, high-output device unit according to claim 2,
wherein the lead has such a shape that one side is longer than the other,
the side of the lead in a longitudinal direction is in contact with a semiconductor package, and
the concave portion provided in the lead is oblong in a longitudinal direction of the lead.

6. The high-frequency, high-output device unit according to claim 5, wherein the concave portion is a groove that continuously extends from an end of the lead to an opposing end of the lead.

7. The high-frequency, high-output device unit according to claim 2, wherein the concave portion provided in the lead is a plurality of openings disposed at grid points.

8. The high-frequency, high-output device unit according to claim 3, wherein the concave portion provided in the lead is oblong grooves crossing each other in a grid form.

9. The high-frequency, high-output device unit according to claims 1, wherein the lead is provided on both of the opposing sides of a semiconductor package.
